(19) United States
(12) Patent Application Publication
(10) Pub. No.: US 2025/0036827 A1
(43) Pub. Date: Jan. 30, 2025

(54) DYNAMIC SUBSTRATE MANAGEMENT FOR DIGITAL TWIN MODELS

(71) Applicant: Dell Products L.P., Round Rock, TX (US)

(72) Inventor: Jaumir Valença da Silveira, JR., Rio de Janeiro (BR)

(21) Appl. No.: 18/361,143

(22) Filed: Jul. 28, 2023

(51) Int. Cl. G06F 30/20; G06F 8/30; G06F 8/35

(52) U.S. Cl. CPC G06F 30/20; G06F 8/315; G06F 8/35

(57) ABSTRACT

One example method includes accessing a definition document that defines a digital twin. A substrate channel component is generated based on the definition document. The substrate channel component is used by the digital twin to communicate with physical entities that provide data to the digital twin. A dynamic substrate manager component is generated based on the definition document. The dynamic substrate manager component dynamically selects which of the physical entities that the digital twin is to be in active communication with so that the selected physical entity can provide data to the digital twin.

### FIELD OF THE INVENTION

Embodiments of the present invention generally relate to digital twin systems and architectures. More particularly, at least some embodiments of the invention relate to systems, hardware, software, computer-readable media, and methods for dynamically selecting devices to be in active communication with a digital twin in digital twin systems and architectures.

### BACKGROUND

A digital twin, by way of example, is a model that corresponds to a physical object or system. The digital twin is, in effect, a digital copy of the physical system. This allows the digital twin to behave like the physical system. Advantageously, the digital twin can ingest data, replicate processes, and the like. This allows the physical system as well as the performance of the physical system to be tested, predicted, monitored, and the like.

The Digital Twin Definition Language (DTDL) is a declarative language used to describe models such as digital twins and can provide a blueprint for sharing knowledge. DTDL allows the description digital twins to be described uniformly. DTDL allows the elements, abilities, behaviors, and other aspects of digital twins to be defined and described.

However, there are aspects of digital twins that are not represented in DTDL. For example, although DTDL provides the concept that a digital twin has commands, there are no features or semantics in DTDL that allow dependencies among the commands to be expressed. Rather, DTDL is an open modelling language for modelling digital twins and is often used as a blueprint to share knowledge between vertical industries.

DTDL is based on the following main logical components: Interface, Telemetry, Property, Command, Relationship, Component, and Primitive Schemas.

The Interface describes the contents (Properties, Telemetries, Commands, Relationships, or Components) of any digital twin. Interfaces are reusable and can be reused as the schema for Components in another Interface. A valid analogy from the Object Oriented programming paradigm would be a “Class”.

Telemetry describes the data emitted by any physical digital twin, whether the data is a regular stream of sensor readings or a computed stream of data or an occasional error or information message.

A Property describes the read-only and read/write state of any digital twin. For example, a device serial number may be a read-only property, the desired temperature on a thermostat may be a read-write property.

A Command describes a function or operation that can be performed on any digital twin.

A Relationship describes a link to another digital twin and enables graphs of digital twins to be created.

A component enables interfaces to be composed of other interfaces. It describes the inclusion of an interface into an interface “by value”. In DTDL v2, a Component cannot contain another Component.

Primitive Schemas are full sets of primitive data types and can be specified directly as the value in a schema statement in a digital twin interface.

In addition to primitive schemas, complex schemas can be created, and schemas can be created at the interface level so they can be shared by Telemetries, Properties and Commands.

Additional information regarding DTDL/DTDLv2 can be found at the following, the contents of which are incorporated by reference in their entirety:
1. https://github.com/Azure/opendigitaltwins-dtdl/blob/master/DTDL/v2/dtdlv2.md (hereinafter “//github” for convenience);
2. https://github#interface;
3. https://github#telemetry;
4. https://github#property
5. https://github#command;
6. https://github#relationship;
7. https://github#component;
8. https://github#primitive-schemas;
9. https://github#complex-schemas.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings.

FIG. 1 discloses aspects of an embodiment of a digital twin system or framework;

FIGS. 2A-2B disclose aspects of an embodiment of a digital twin system or framework that includes a substrate channel;

FIGS. 3A-3D disclose aspects of an embodiment of a digital twin system or framework that includes a substrate channel and a dynamic substrate manager;

FIGS. 4A-4G disclose aspects of an object oriented framework of a substrate channel;

FIGS. 5A-5C disclose aspects of an object oriented framework of a dynamic substrate manager;

FIG. 6 discloses aspects of code generation;

FIGS. 7A-7D disclose aspects of DTDL model and object oriented framework for a joystick directional component and button component;

FIGS. 8A-8B disclose aspects of typed relationship between a DTDL model of a joystick and a DTDL model of a substrate channel;

FIGS. 9A-9B disclose aspects of typed relationship between a DTDL model of a dynamic substrate manager and a DTDL model of a substrate channel; and

FIG. 10 discloses aspects of a computing device, system, and/or entity.

### DETAILED DESCRIPTION OF SOME EXAMPLE EMBODIMENTS

Embodiments of the present invention generally relate to digital twin systems and architectures. More particularly, at least some embodiments of the invention relate to systems, hardware, software, computer-readable media, and methods for dynamically selecting devices to be in active communication with a digital twin in digital twin systems and architectures

A definition for “digital twin” may be stated as any physical entity or device, mechanism or process that has a virtual representation in a computer runtime environment. The physical entity or device, mechanism or process sends data regularly to the respective digital twin, which in turn updates its state. By “state” we mean the value of its internal attributes or variables. A Runtime Environment executes the instantiation of different types of digital twins, and the change in a digital twin's state can cause change on the state of other digital twins.

The digital twin framework generalizes this one-to-one, physical-to-digital twin concept into a many-to-one concept, where one digital twin can be dynamically linked to multiple data sources, and a score-based mechanism is embedded to decide, at different points in time, which data source has more suitable data to be used to update its state. This approach can be useful in several scenarios where digital twins are employed, such as Industrial Product Manufacturing, where sometimes parts of a product must be tested either with simulated data or with real device data, or dynamic selection of Machine Learning models, among others.

The present disclosure presents this framework entirely in the Digital Twin Descriptive Language (DTDL), using the DTDL to describe software design components, as opposed to its original purpose of solely describing digital twins for business domains. The embodiments disclosed herein introduce the concept of DTDL typed relationships and uses them to link the herein described framework components in a way that imperative source code can be easily generated from a full DTDL model that encompasses both Business and Design digital twins. Finally, the embodiments disclosed herein give directions to code generation of the components described via DTDL in any current Object-oriented language.

One example method includes accessing a definition document that defines a digital twin. A substrate channel component is generated based on the definition document. The substrate channel component is used by the digital twin to communicate with physical entities that provide data to the digital twin. A dynamic substrate manager component is generated based on the definition document. The dynamic substrate manager component dynamically selects which of the physical entities that the digital twin is to be in active communication with so that the selected physical entity can provide data to the digital twin.

Embodiments of the invention, such as the examples disclosed herein, may be beneficial in a variety of respects. For example, and as will be apparent from the present disclosure, one or more embodiments of the invention may provide one or more advantageous and unexpected effects, in any combination, some examples of which are set forth below. It should be noted that such effects are neither intended, nor should be construed, to limit the scope of the claimed invention in any way. It should further be noted that nothing herein should be construed as constituting an essential or indispensable element of any invention or embodiment. Rather, various aspects of the disclosed embodiments may be combined in a variety of ways so as to define yet further embodiments. For example, any element(s) of any embodiment may be combined with any element(s) of any other embodiment, to define still further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

It is noted that embodiments of the invention, whether claimed or not, cannot be performed, practically or otherwise, in the mind of a human. Accordingly, nothing herein should be construed as teaching or suggesting that any aspect of any embodiment of the invention could or would be performed, practically or otherwise, in the mind of a human. Further, and unless explicitly indicated otherwise herein, the disclosed methods, processes, and operations, are contemplated as being implemented by computing systems that may comprise hardware and/or software. That is, such methods processes, and operations, are defined as being computer-implemented.

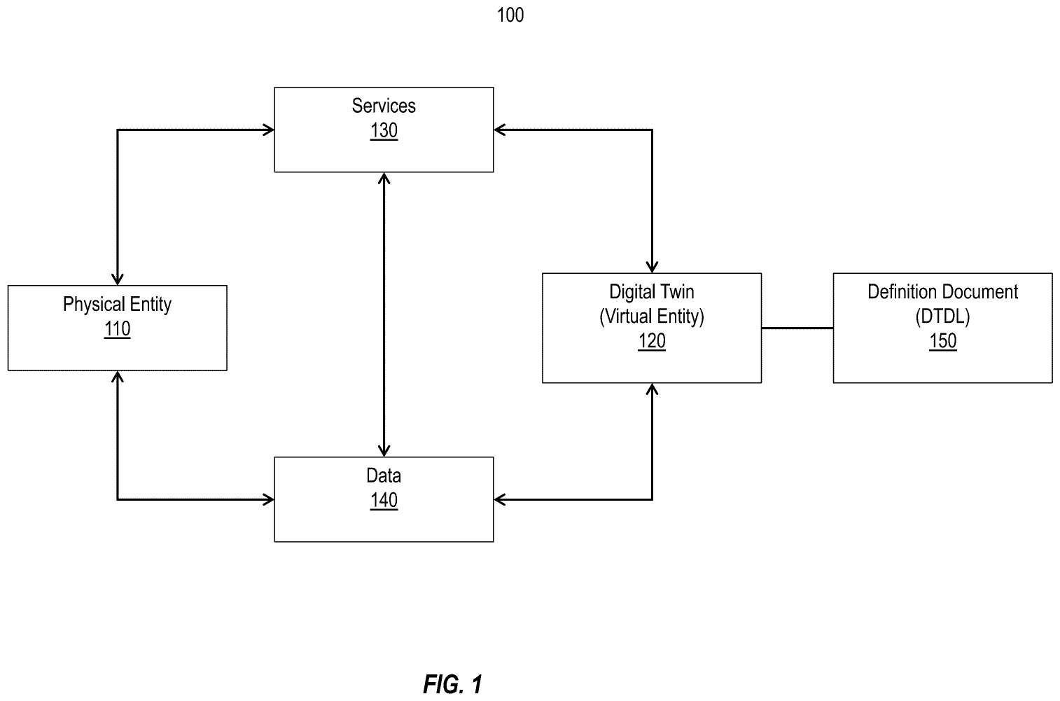

FIG. 1 discloses aspects of a digital twin system or framework 100. By way of example, a digital twin framework or system may include five dimensions: physical entity, virtual entity, services, connection, and digital data. The digital twin system 100 include a physical entity 110, which may also be called a physical substrate or a physical device. The physical entity 110 may include or represent various systems, subsystems, and sensory devices, such as, but not limited to, a dynamic system, a control system, a hydraulic system, sensors, design, manufacturing, or the like. The digital twin 120 (virtual entity) may be a mirror of the physical entity 110 and may include geometry models, physics models, behavior models, rule models, or the like or combination thereof.

The services 130 are configured to ensure that the physical entity 110 operates as expected and sustains high-fidelity of the digital twin 120 through model parameters calibration. For the physical entity 110, the services 130 may include monitoring, state prediction, optimization, or the like. For the digital twin 120, the services may include construction services, calibration services, test service models, and the like. The connections represent possible connections, which may be bidirectional, between the services 130, the physical entity 110, the digital twin 120, and data 140. The data 140 may be a database that stores data from the physical entity 110, the digital twin 120, from services 130, and fusions or combinations thereof.

The digital twin 120 may be defined by a definition document 150, an example of which is a Digital Twin Definition Language (DTDL) document. The definition document 150, in accordance with embodiments of the invention, may express or include command dependencies.

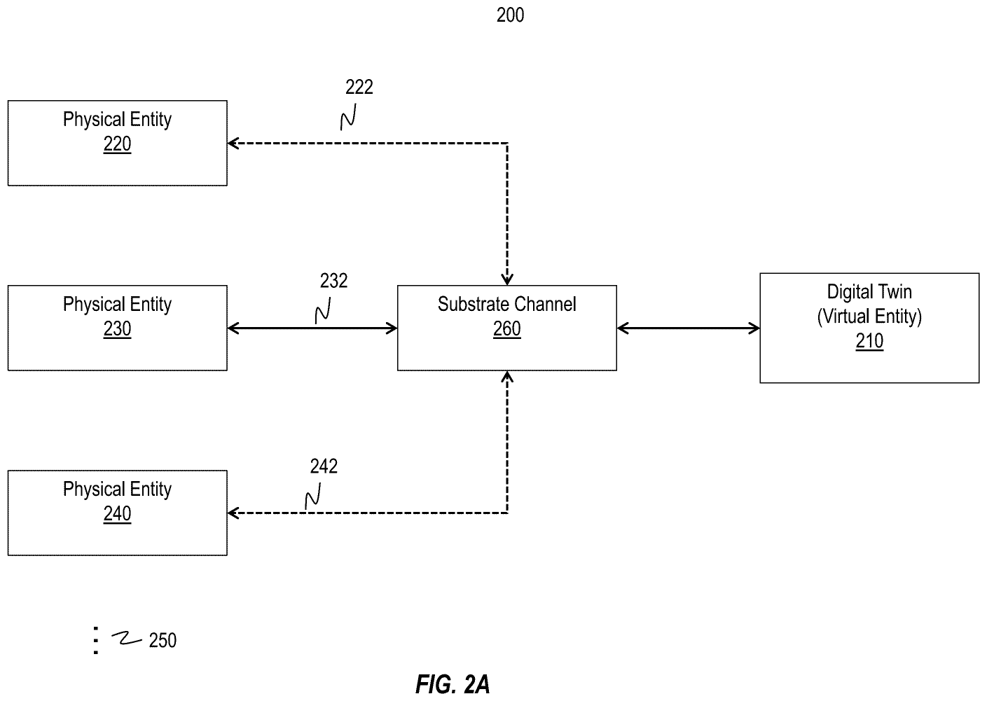

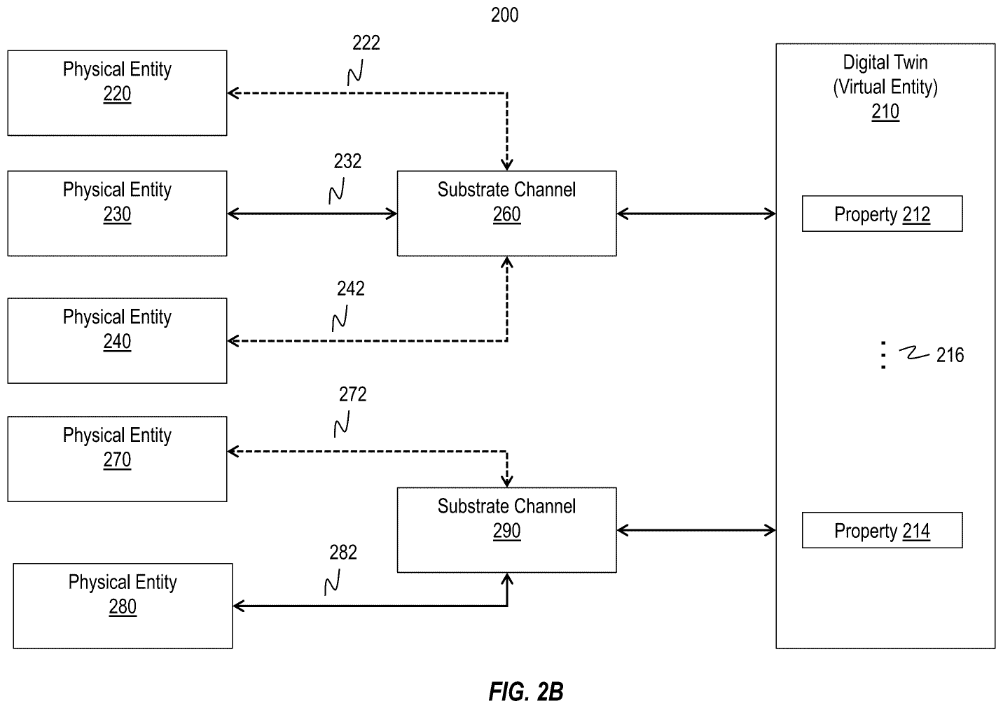

FIG. 2A discloses aspects of a digital twin system or framework 200, which may correspond to the digital twin system 100 of FIG. 1. Accordingly, although not illustrated the digital twin system 200 includes service and data that are associated with the physical entities and the digital twin in the manner previously described.

As illustrated, the digital twin system 200 includes a digital twin (virtual entity) 210, which may correspond to the digital twin 120 and may be defined by a definition document such as the definition document 150. However, in the digital twin system 200, the digital twin 210 mirrors more than one physical entity. For example, the digital twin 210 is able to mirror a physical entity 220, a physical entity 230, a physical entity 240, and any number of additional physical entities 250 as illustrated by the ellipses. The physical entities 220, 230, 240, and 250 may correspond to the physical entity 110 and thus may also be called physical substrates or physical devices.

The digital twin 210 is connected to and communicates with the physical entities 220, 230, 240, and 250 via a substrate channel 260. Thus, the substrate channel 260 allows the digital twin 210 to receive data from the physical entities 220, 230, 240, and 250 that are used by the digital twin to update the state of the digital twin and allows the digital twin 210 to provide state updates and other relevant information to one or more of the physical entities 220, 230, 240, and 250. The substrate channel 260 is a configurable channel that is able to change which of the physical entities 220, 230, 240, and 250 is currently communicating with the digital twin 210 so as to be able to provide data to the digital twin and receive data from the digital twin. That is, only one of the physical entities at a time communicates with the digital twin 210 and the substrate channel 260 is able to change which physical entity is actively communicating with the digital twin. For example, in FIG. 2A the solid line 232 illustrates that the physical entity 230 is currently in active communication with the digital twin 210 via the substrate channel 260. The dashed lines 222 and 242 illustrate that the physical entities 220 and 240 are not in current communication with the digital twin 210. The configurable nature of the substrate channel 260 will be explained in more detail to follow.

FIG. 2B discloses aspects of an alternative embodiment of the digital twin system or framework 200. As illustrated, the digital twin system includes the digital twin 210. In the embodiment, the digital twin 210 includes properties 212, 214, and any number of additional properties 216 as illustrated by the ellipses. Each property may define a state of the digital twin 210 as it is mirroring one or more physical entities. For example, if the digital twin 210 is mirroring a security system, the property 212 may be a state of various security cameras of the security system and the property 214 may be the state of various motion sensors of the security system. Accordingly, in such embodiments each property may communicate with various physical entities via a substrate channel.

As illustrated, the property 212 communicates with the physical entities 220, 230, 240, and (not illustrated) 250 via the substrate channel 260. As discussed in relation to the FIG. 2A, the substrate channel 260 is configurable so that only one physical device communicates with the property 212 at a time, but that substrate channel 260 can change which physical device is in active communication.

The property 214 communicates with a physical entity 270 and a physical entity 280 via a substrate channel 290. The substrate channel 290 is configurable in the same manner as the substrate channel 260. Thus, in FIG. 2B the solid line 282 illustrates that the physical entity 280 is currently in active communication with the digital twin 210 property 214 via the substrate channel 290. The dashed line 272 illustrated that the physical entity 270 is not in current communication with the digital twin 210 property 214. Although not illustrated, the additional properties 216 can also communicate with various physical entities via additional substrate channels.

As discussed above, a digital twin can be connected to multiple physical entities via the substrate channel, but will only actively communicate with one of the physical entities at a time. However, during operation, the digital twin will often have a need to change which of the physical entities it is actively communicating with. For example, in one embodiment one of the physical entities could be a joystick and another of the physical entities could be a joystick simulator. In such embodiment, if the signal from the joystick to the digital twin became diminished for some reason such as a bad connection, then the digital twin would need to switch to the joystick simulator to continue its operation. Accordingly, the embodiments disclosed herein provide for a way to determine which physical entity should be actively in communication with the digital twin and provide a way to cause the substrate channel to switch or to make active the communication between the digital twin and physical entity who it is determined should be in active communication.

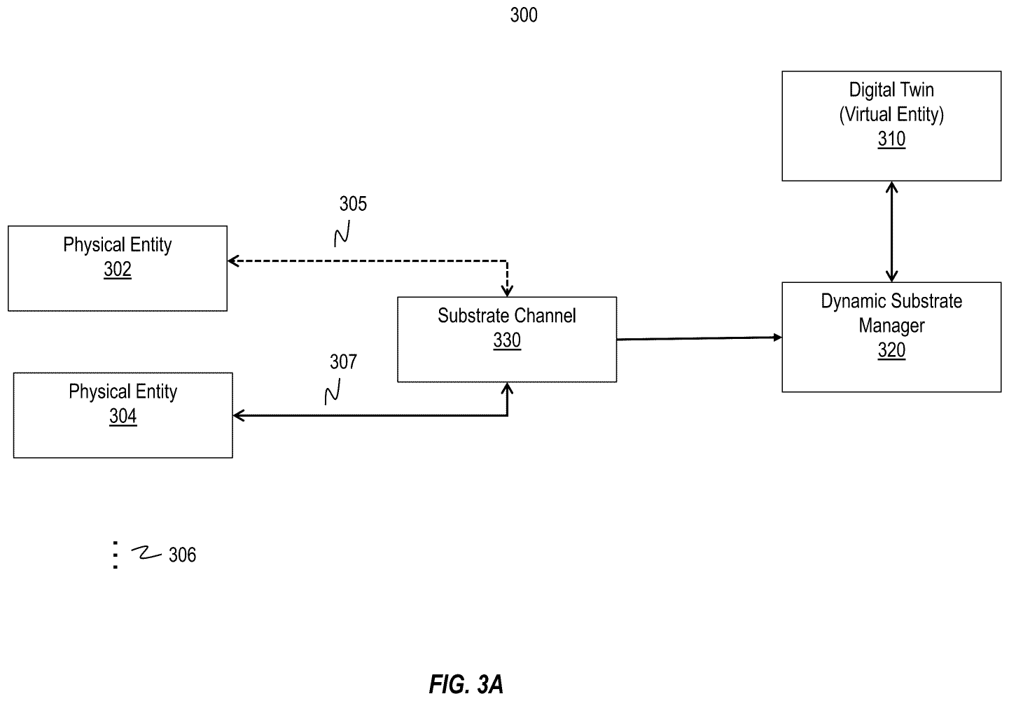

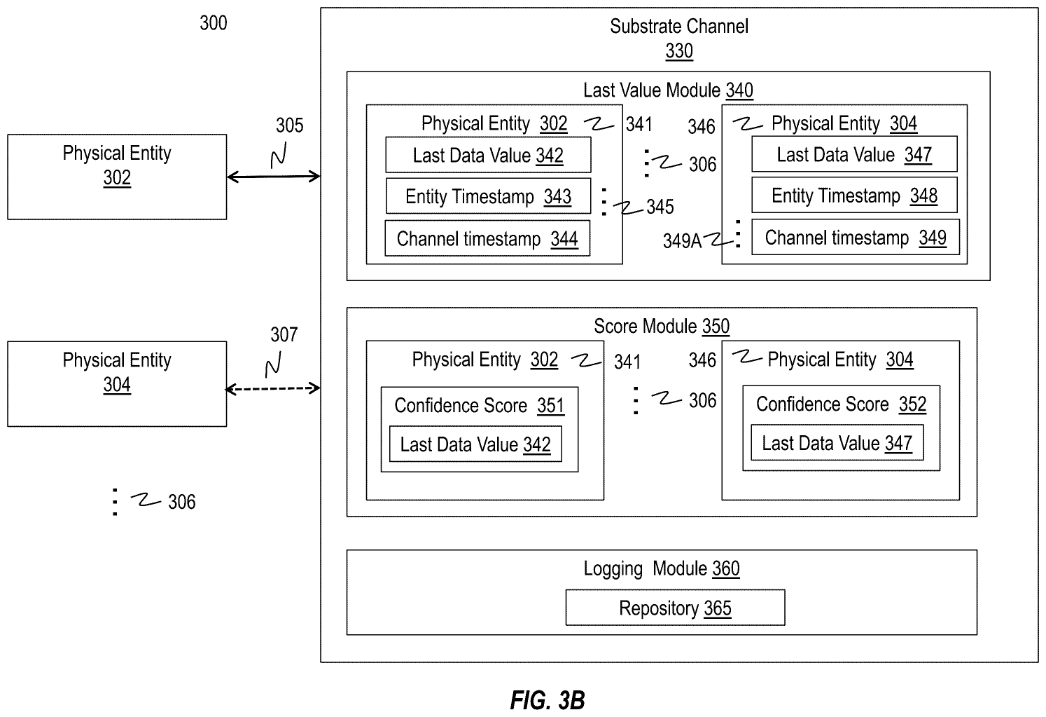

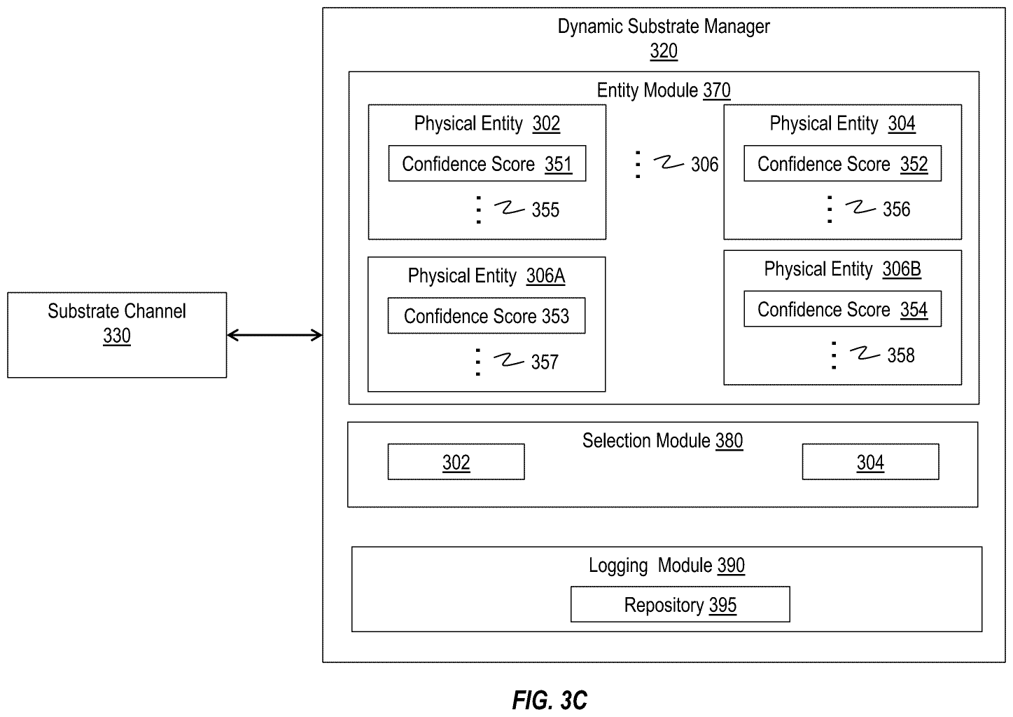

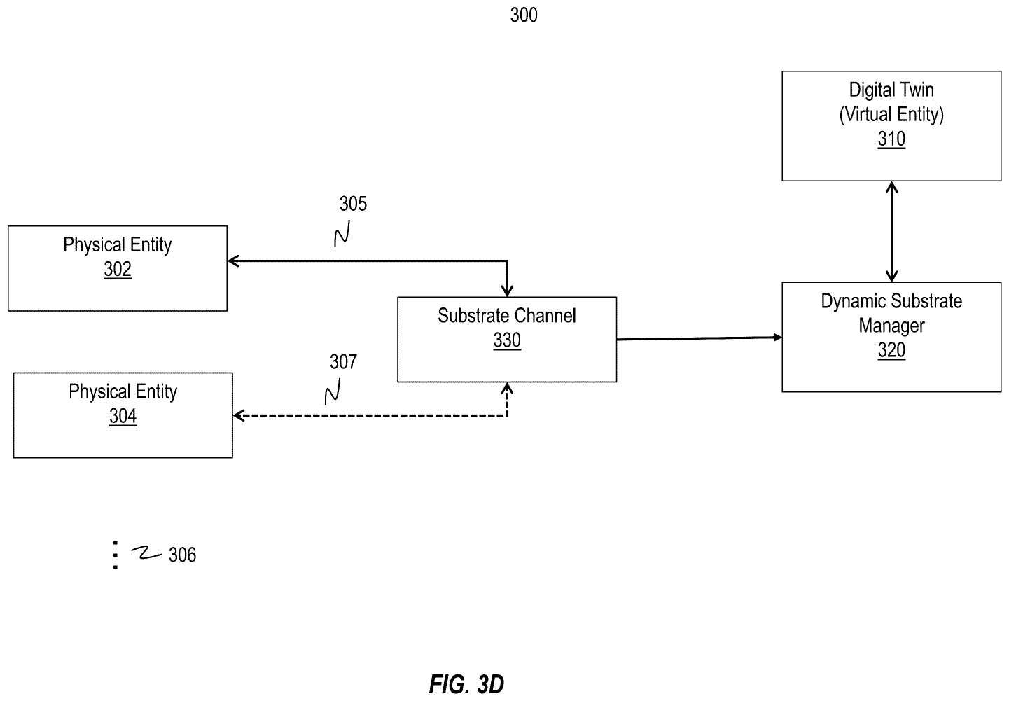

FIG. 3A discloses aspects of a digital twin system 300 that includes a digital twin 310 that corresponds to the digital twins previously described. The digital twin system also includes a configurable substrate channel 330 that corresponds to the substrate channels previously described and physical entities 302, 304, and potentially any number of physical entities 306 as illustrated by the ellipses, and that correspond to the physical entities previously described. The solid line 305 illustrates that the physical entity 302 is currently in active communication with the digital twin 310 via substrate channel 330 and the dashed line 307 illustrates that the physical entity 304 is not in active communication with the digital twin 310. Although not illustrated, none of the additional physical entities 306 are in active communication with the digital twin 310.

The digital twin system 300 also includes a dynamic substrate manager 320 that is advantageously able to determine which physical entity should be actively in communication with the digital twin and is able to provide a way to cause the substrate channel to switch or to make active the communication between the digital twin and physical entity who it is determined should be in active communication. The operation and configuration of the dynamic substrate manager 320 and the substrate channel 330 will now be explained. It will be appreciated that the operation and configuration described in relation to FIGS. 3A-xxx will apply to the various embodiments previously described. It will also be appreciated that although the dynamic substrate manager 320 and the substrate channel 330 are shown as being separate from the digital twin 310, this for ease of explanation only as in some embodiments the dynamic substrate manager 320 and the substrate channel 330 are implemented as part of digital twin 310 and are included in a definition document that defines the digital twin 310.

FIG. 3B illustrates a portion of the digital twin system 300. As illustrated, FIG. 3B illustrates the physical entities 302, 304, and 306 and a detailed view of the substrate channel 330. The substrate channel 330 includes a last value module 340. In operation, the last value module 340 listens to the data flow or telemetries that are arriving from the physical entities 302, 304, and 306. For each of the physical entities, the last value module specifies an identification or URI and logs a last data value. The last data value is the most recent data or telemetry received from a physical entity. Once a new data value is received, the existing data value is discarded. The last value module also records an entity time stamp that specifies a time the last data value left the physical entity and a channel timestamp that specifies when the last data value is received at the substrate channel.

For example, the last value module 340 specifies an identification 341 for the physical entity 302 and logs a last data value 342 received from physical entity 302. The entity timestamp 343 specifies the time the last data value 342 left the physical entity 302 and the channel timestamp 344 specifies when the last data value 342 was received by the substrate channel 330. The ellipses 345 represent that the last value module 340 may log additional information about the physical entity 302 such as authentication information that is used by the physical entity 302 to authenticate itself with the substrate channel 330.

Similarly, the last value module 340 specifies an identification 346 for the physical entity 304 and logs a last data value 347 received from physical entity 304. The entity timestamp 348 specifies the time the last data value 347 left the physical entity 304 and the channel timestamp 349 specifies when the last data value 347 was received by the substrate channel 330. The ellipses 349A represent that the last value module 340 may log additional information about the physical entity 304 such as authentication information that is used by the physical entity 304 to authenticate itself with the substrate channel 330.

The substrate channel 330 also includes a score module 350. In operation, the score module 350 generates a confidence score for the last value logged by the last value module 340. The confidence score is a measure of how reliable the last data value is. For example, if the last data value is of high quality such that it can be easily read by the substrate channel, then a relatively high confidence score may be determined by the score module 350. However, if the last data value is of low quality such that it cannot be easily read by the substrate channel, then a relatively low confidence score may be determined. In some embodiments, the specific mechanism implemented by the score module 350 to determine the confidence score is dependent on the application domain in which the substrate channel 330 is inserted. Thus, the specific implementation of the score module 350 will change depending on the business domain of the digital twin system 300. In one embodiment, the confidence score may be assigned as either the values {0,1}, meaning that the last values is reliable or not. In other embodiments, the confidence score could be a range of values, meaning that the last score could be less reliable or more reliable depending on the score value.

As illustrated in FIG. 3B, the score module 350 determines a confidence score 351 for the last data value 342 of the physical entity 302. The score module also determines a confidence score 352 for the last data value 347 of the physical entity 304. Although not illustrated, the score module 350 determines a confidence score for the last data value of any physical entity 306.

In some embodiments, the substrate channel 330 includes a logging module 360. In operation, the logging module 360 logs the history of last data values. Thus, the last data values that are replaced by new data values are retained and may be used for various purposes such as the analysis of the quality of the received data or the detection of spurious data. The historical last data values may be stored in a repository 365, that may be part of the digital twin system 300 or may be part of a differing computing system.

FIG. 3C illustrates a portion of the digital twin system 300. As illustrated, FIG. 3B illustrates the substrate channel 330 and a detailed view of the dynamic substrate manager 320. As illustrated, the dynamic substrate manager 320 includes an entity module 370. In operation, the entity module 370 receives the confidence scores for each entity from the substrate channel 330. For example, the entity module 370 receives the confidence score 352 for the physical entity 302 and the confidence score 352 for the physical entity 304. FIG. 3C also illustrates that the entity module 370 receives a confidence score 357 for a physical entity 306A and a confidence score 358 for a physical entity 306B. It will be noted that the physical entities 306A and 306B are examples of the additional physical entities 306 and that the ellipses represent that there may be further additional physical entities 306 whose confidence score is received by the entity module 370. In some embodiments, the entity module 370 also receives additional information about a physical entity such as the last value data value or the timestamps previously described as illustrated by the ellipses 355, 356, 357, and 358 respectively.

The dynamic substrate manager 320 also includes a selection module 380. In operation, the selection module 380 uses the confidence scores received by the entity module 370 to select which physical entity should be actively in communication with the digital twin 310. The operation of the selection module 380 will be explained in more detail to follow.

In some embodiments, the dynamic substrate manager 320 also includes a logging module 390. In operation, the logging module 390 logs the history of the confidence scores (also referred to as last scores) received by the entity module. Thus, the last confidence scores that are replaced by new confidence scores are retained and may be used for various purposes such as the analysis of the quality of the received confidence scores. The historical confidence scores may be stored in a repository 395, that may be part of the digital twin system 300 or may be part of a differing computing system and which may be the same repository as the repository 365 or may be a different repository.

The operation of the digital twin system 300 including the operation of the substrate channel 330 and the dynamic schedule manager 320 will now be explained. During operation, the substrate channel 330 logs the last data values 342 and 347 and then determines the confidence scores 351 and 352 for the physical entities 302 and 304 respectively. The substrate channel 330 also logs last data values and determines confidence scores for any additional physical entities 306. The dynamic substrate manager 320 receives the confidence scores 352 and 354 (and any confidence scores for the additional physical entities 306) and selects the physical entity who is best suited for active communication with the digital twin 310.

As previously discussed, FIG. 3A shows that the physical entity 304 is in active communication with the digital twin 310. Accordingly, in the time period of FIG. 3A the selection module 380 has selected the physical entity 304 based on the confidence score 352 for active communication with the digital twin 310. For example, the confidence score 352 may be higher than any of the other confidence scores or may be higher than a present threshold. The dynamic substrate manager 320 directs the substrate channel 330 to cause the physical entity 304 to be in active communication.

As previously discussed, the process of the substrate channel 330 logging the last data values and generating the confidence scores and the dynamic substrate manager 320 using the confidence scores to determine best suited for active communication with the digital twin 310 is a continual process. Accordingly, at a time period later than the time period of FIG. 3A, the dynamic substrate manager 320 may determine based on confidence scores 351 and 352 that the physical entity 302 is now best suited for active communication with the digital twin 310. For example, as discussed previously, in the time period of FIG. 3A, the confidence score 352 was higher than the confidence score 351. However, the selection module 380 may now determine that the confidence score 351 is higher than the confidence score 353 and so select the physical entity 302 to be in active communication with the digital twin 310.

For example, the physical entity 304 could be a joystick and the physical entity 302 could be a joystick simulator. In such embodiment, if the signal from the joystick to the digital twin became diminished for some reason such as a bad connection, then the digital twin would need to switch to the joystick simulator to continue its operation. Accordingly, as illustrated in FIG. 3D, the dynamic substrate manager 320 directs the substrate channel 330 to cause the physical entity 302 to be in active communication with the digital twin 310 as shown by the solid line 305 and to cause that the physical entity 304 to no longer be in active communication as shown by the dashed line 307. Thus, the dynamic manager 320 is able to constantly monitor and change which physical entity is in active communication with the digital twin 310 to ensure that the physical entity that will provide the best data to the digital twin is always in active communication.

Although the operation of the dynamic substrate manager 320 was illustrated for a digital twin 310 having a single substrate channel 330, it will be appreciated that the dynamic substrate manager can perform this action for digital twins associated with more than one substrate channel. Thus, for a digital twin such as the digital twin 210 shown in FIG. 2B, a substrate channel manger such as the substrate channel manager 320 is able to determine which physical entity is best suited for active communication with the digital twin 210 for all of the associated substrate channels such as the substrate channel 260 and the substrate channel 290.

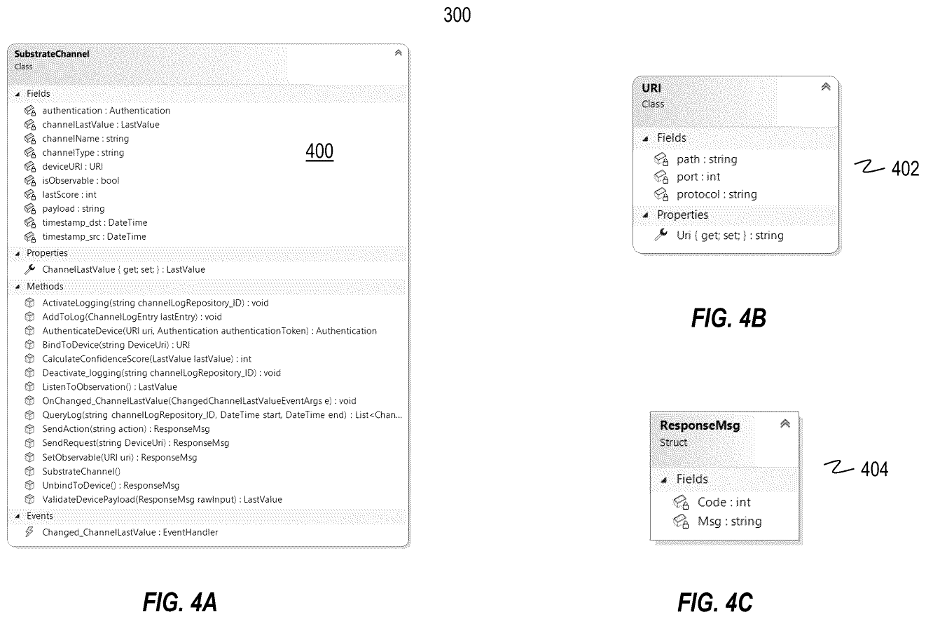

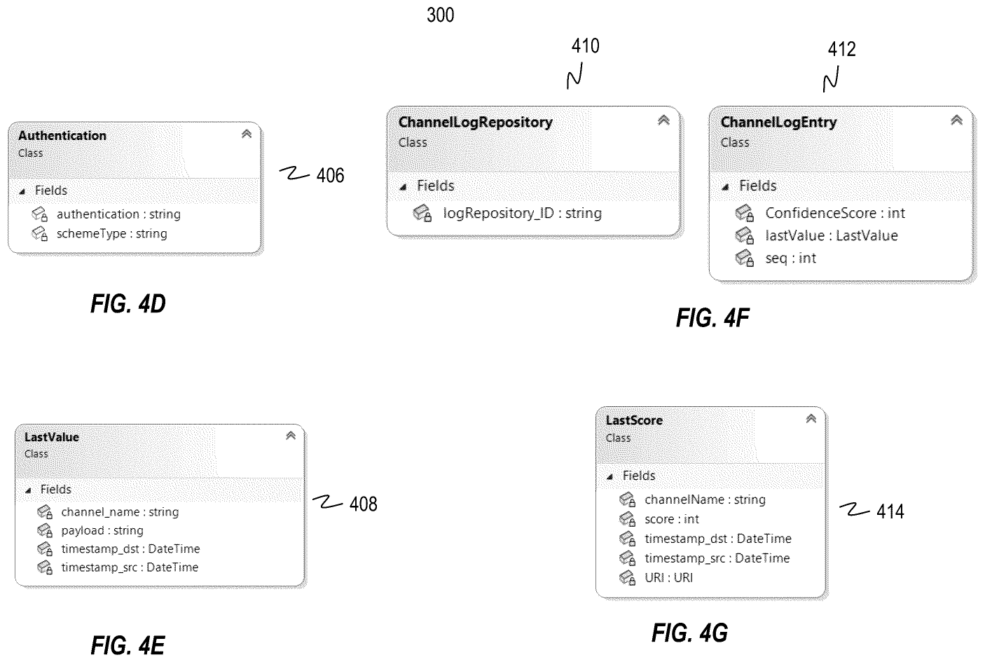

In some embodiments, the substrate channel 330 and the dynamic substrate manager 320 can be implemented as an Object Oriented (OO) framework which will now be explained. FIG. 4A discloses example OO method declarations of the substrate channel 330 that can be generated from a DTDL specification such as that shown in the Appendix to this application. The functions and methods are a declared SubstrateChannel class 400 of FIG. 4A. A description of the SubstrateChannel class 400 with its methods and properties follows. It should function as a blueprint for the most important mechanisms that the framework should provide, i.e., minor changes on the architecture are not critical as long as they do not compromise its main responsibilities:
Connect to a substrate on a closed-loop fashion, i.e., control the data flow between substrate and Digital Twin and update the Digital Twin state with last values received from substrate.
Optional logging of received data from substrate.
Provide a mechanism for scoring data retrieved from the substrate.

FIG. 4B illustrates a URI class 402 for communication. The URI class 402 functions as a physical entity identifier and is the basic communication address construct. The URI as a Property is composed of three fields: Protocol, Path, and Port. This abstraction is used in communications between a physical entity (device) and the substrate channel.

FIG. 4C illustrates a ResponseMsg class 404, which is used in communication between the digital twin and a physical entity. The communication is simple, mostly a request-response stateless protocol. The response should contain, along with the data payload, an error code. There are two communication scenarios: (i) a direct request of data from the digital twin to the physical entity, or (ii) the digital twin can signal to the physical entity that it is an observer; in this case, the physical entity must send regular data to the digital twin without the need of a request.

FIG. 4D illustrates an authentication class 406. An AuthenticateDevice( ) command is provided by the substrate channel that can be used by a physical entity to authenticate itself, by passing as a parameter some string that can be recognized and authenticated by the substrate channel. If the Authentication is successful, the substrate channel will store an Authentication object for further communication with the respective physical entity.

Once a physical entity is authenticated, it can be bound to the substrate channel. The framework also allows for unbinding the device from the substrate channel, allowing for another physical entity to be bound dynamically. A substrate channel method BindToDevice( ) checks if the physical entity is already authenticated and, if it is, its URI property is set.

The substrate channel object can signal to the physical entity that it is in observer mode, meaning that the substrate channel will not request each telemetry data message; instead, the physical entity is responsible for sending telemetry data regularly. The substrate channel object provides a SetObservable( ) method and should receive a response from the physical entity stating if it complies or not with this pattern.

FIG. 4E illustrates a LastValue class 408. The substrate channel object has a ListenToObservation( ) command that listens to telemetry data arriving from a physical entity, and a LastValue property where it stores the last telemetry data received, always discarding the old value. The stored LastValue should have, along with the specific data payload for the application, two timestamps: one timestamp for the time the message left the d physical entity, and another timestamp for the time it arrived at the substrate channel component. These two timestamps are important for the implementation of a GetLastDelay( ) command, which retrieves the difference between these two timestamps.

As discussed above, the substrate channel 330 is able to propagate changes to the last value to the dynamic substrate manager. In one embodiment, the substrate channel 330 implements a state propagation mechanism using the event handling mechanism available as part of the OO language C#. However, several other OO languages provide similar functionality.

Each time the property LastValue of the substrate channel is changed, an event is raised, allowing for its value to be used by other objects in the digital twin system. The mechanism by which other objects in the digital twin system can be notified of its change is by adding an event handler method of the referred digital twin to the Changed_ChannelLastValue event. Doing so, when the LastValue of a substrate channel object is changed, will execute all event handlers that were added to its Changed_ChannelLastValue event. The following is an example embodiment of an OO language event handling mechanism.

```
// Place to register methods (event handlers) from other objects
//
public event EventHandler Changed_ChannelLastValue;
// This method executes all event handlers
//
public void
OnChanged_ChannelLastValue(ChangedChannelLastValueEventArgs e)
{
  var boundDelegates =
  Changed_ChannelLastValue.GetInvocationList( );
  foreach (Delegate boundDelegate in boundDelegates)
  {
    Changed_ChannelLastValue(this, e);
  }
}
// Implemented as an OO property
// Allows all event handlers to be executed when property changes
//
public LastValue ChannelLastValue
{
  get => default;
  set
  {
    // Operations hidden from clients
    // CalculateConfidenceScore( ) added after code generation
    //
    this.lastScore = CalculateConfidenceScore(this.channelLastValue);
    this.channelLastValue = value;
      // Preparing parameters to pass to event handlers
    //
    var eventArgs = new ChangedChannelLastValueEventArgs
      (this.ChannelLastValue, this.lastScore);
    // Gets a list of event handlers and executes them in order
    //
    OnChanged_ChannelLastValue(eventArgs);
  }
}
```

FIG. 4F illustrates a logging mechanism for logging the history of LastValues that one physical entity sends to the substrate channel and that can be used for several purposes, such as analyses of the quality of the data or detection of spurious data that might have compromised the system as a whole. In some embodiments, the logging mechanism is optional. The logging mechanism includes a ChannelLogRepository class 410 and a ChannelLogEnrty class 412. A log entry should have a timestamp along with the LastValue and the ConfidenceScore given to that value.

The logging system, in its simplest embodiment, should implement at least these mechanisms:
ActivateLogging—Links the Substrate Channel to a Repository object and starts the logging process.
DeactivateLogging—Stops the logging process.
QueryLog—Given a StartDate and an EndDate, get a list of log entries for a workload in a specific repository.

FIG. 4G illustrates a LastScore class 414. The substrate channel gives each Last Value a score, which represents the confidence level of that last score. The framework provides a function interface CalculateConfidenceScore( ) which is called immediately after the LastValue property of the substrate channel is changed and returns an instance of the LastScore class 414, recording the score and relevant timestamps.

The substrate channel performs the following actions to determine the confidence scores:
ListenToObservation( )—A value (e.g., telemetry value) is received by the Substrate Channel;
ValidateDevicePayload( ) and UpdateLastValue( )—The received value is validated and stored in the Digital Twin as its LastValue property;
CalculateConfidenceScore( )—The Confidence Score is calculated for this LastValue;
Its LastScore property will be updated with the new confidence score.
   As discussed previously, the last score can be used by the dynamic substrate manager to decide which physical entity, via the substrate channel, should be currently active.

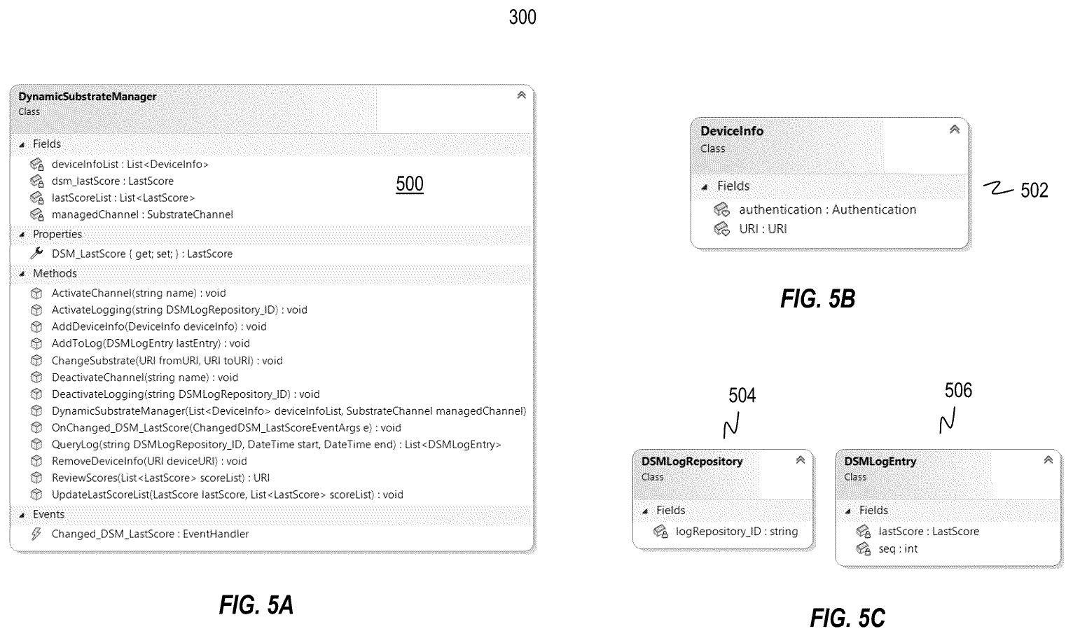

FIG. 5A discloses example OO method declarations of the substrate channel 330 that can be generated from a DTDL specification such as that shown in the Appendix to this application. The functions and methods are a declared DynamicSubstrateManager class 500 of FIG. 5A. As discussed previously, the dynamic substrate manager 320 works in conjunction with the substrate channel 330 as follows:
It stores a list of URIs (physical entity IDs) that correspond to the physical entities that the Substrate Channel can use, along with an authorization object for each of these devices. FIG. 5B illustrates a DeviceInfo class 502 that is used to show that each physical entity (or data source) has an URI and an Authorization scheme.
It stores a list of LastScores, where each list element corresponds to a different URI stored in the URI list; i.e., it stores the LastScore produced by each physical entity.
It gets the LastScore value given by the substrate channel each time it is changed, via subscription to event Changed_Channel_lastValue exposed by the cubstrate channel.
Based on each LastScore received, it compares it to the LastScore of each URI on its list and decides if it keeps the current URI as substrate or changes it in the substrate channel instance it is managing.

Similar to the substrate channel, the dynamic substrate manager also exhibits the possibility to execute methods (event handlers) from other objects when the DSM_LastScore property changes. This allows other objects to be notified when the LastScore changes—not only the score, but also from which substrate it came from. In this OO representation, the event Changed_DSM_LastScore is responsible for registering event handlers from other objects.

The basic mechanism for the dynamic selection of a physical device is as follows:
When the substrate channel LastValue changes, the dynamic substrate manager is notified;
With this given LastScore, ReviewScores( ) reviews all last scores from all substrates (using the lastScoreList) and decides if the current substrate is still the most suitable or should be replaced by another substrate;
If needed, Updates the list of last scores and changes the physical entity for that substrate channel.

The following is an example embodiment of an OO language mechanism for dynamically selecting a physical entity:

```
public LastScore DSM_LastScore
{
get => default;
set
{
  this.dsm_lastScore = value;
  // (Added after code generation)
  // The ReviewScores( ) method is domain-specific and should be
  // further implemented
  //
  this.UpdateLastScoreList(dsm_lastScore, this.lastScoreList);
  var newURI = this.ReviewScores(this.lastScoreList);
  if (dsm_lastScore.URI != newURI)
  {
  this.ChangeSubstrate(dsm_lastScore.URI, newURI);
  }
  // Preparing parameters to pass to event handlers
  //
  var eventArgs = new
  ChangedDSM_LastScoreEventArgs(dsm_lastScore);
  // Gets a list of event handlers and executes them in order
  //
  OnChanged_DSM_LastScore(eventArgs);
}
}
```

FIG. 5C illustrates a logging mechanism for logging the history of LastScores that the substrate channel provides to the dynamic substrate manager and that can be used for several purposes, such as analyses of the quality of the data or detection of spurious data that might have compromised the system as a whole. In some embodiments, the logging mechanism is optional. The logging mechanism includes a DSMILogRepository class 504 and a DSMLogEnrty class 506. A log entry should have a timestamp along with the LastValue and the ConfidenceScore given to that value.

The logging system, on its simplest embodiment, should implement at least these mechanisms:
ActivateLogging—Links the Dynamic Substrate Manager to a Repository object and starts the logging process.
DeactivateLogging—Stops the logging process.
QueryLog—Given a StartDate and an EndDate, get a list of log entries for a workload in a specific repository.

The score system used to determine the current best physical entity can rely only on the last score value given by the substrate channel, or it can use a range of previously stored last values of all physical entities. In the first case, the score system is considered memoryless, and in the last case the score system is considered memory-based.

Both substrate channel and dynamic substrate manager envision the possibility of storing values along the time, creating time series:
the substrate channel object can store the obtained last values each time it receives data from the physical entity(i.e., the full payload received from the physical entity) along with the scores generated for the data;
the dynamic substrate manager object stores only the last scores that were given by the substrate channel.

The dynamic substrate manager can, therefore, use both sets of information when deciding if it needs to change the substrate. For a lightweight memory-based decision, it can query only DSMLog entries. For business cases that do not require a quick response by the dynamic substrate manager, the dynamic substrate manager can query the substrate channel linked to it for a range of Last Values, containing the full payload of the received data.

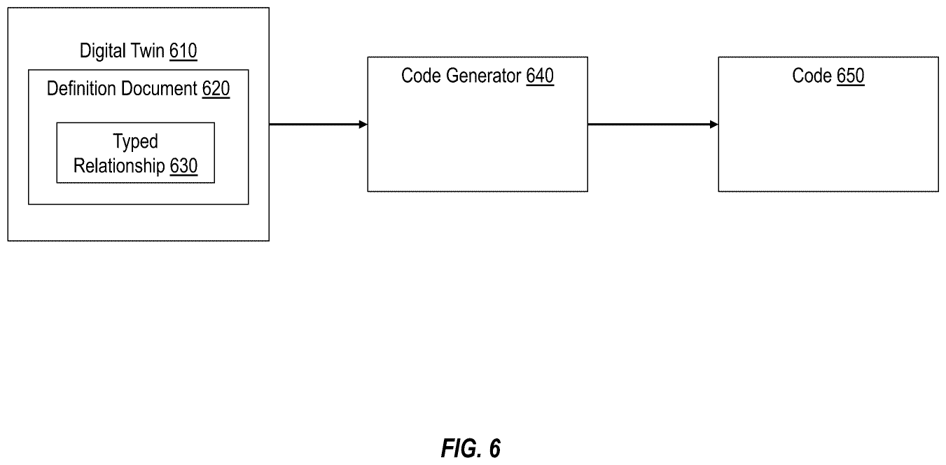

Embodiments of the invention also relate to a digital twin 610 that is able to generate code from a definition document 620 to an object orientated programing language. FIG. 6 illustrates a code generator 640 that can convert the definition document 620 to code 650. More specifically in one example, the code generator 640 may convert aspects of the definition document 620 related to commands, command execution, and/or command dependencies to code 650. As will be explained in more detail to follow, the code may be generated using a typed relationship 630. Embodiments of the invention can create code in different programming languages. An example of generating code 650 from a definition document 620 such as a DTDL document is illustrated.

In one example, general rules are implemented by the code generator 640 that allow code 650 to be generated in different programming languages. The rules for generating the definition document 620, however, are distinct and independent from rules for generating the code 650 different languages. Generating the definition document 620, for example, does not require the code to be generated. Rather, the ability to include a schema for orchestrating commands in the definition document is what allows, if desired, the code 650 to be generated automatically. The specific language may depend on the target field of the relationships. Example rules for generating OO code (e.g., code 650) from a DTDL description (e.g., definition document 620 or portion thereof such as a relationship) include:
1. DTDL interfaces as well as components become OO classes.
2. A DTDL Property without an ID becomes an OO field (private or protected attribute).
3. A DTDL Property with an ID becomes an OO property (public attribute).
4. Complex schemas of type Object declared in section Schemas of a DTDL interface become classes in the scope of the DTDL interface that owns that Schemas section.
5. DTDL Telemetries become OO Properties.
6. Moreover, language-specific mechanisms for event handling should be added to allow for OO properties to accept a list of functions that should be executed each time an OO property value is changed.
7. Simple schemas map to simple types (e.g., string, integer); complex schemas, however, can be mapped to:
   a. Array->OO list
   b. Enum->OO enumeration
   c. Map->OO dictionary
   d. Object->OO class.
8. Command declarations are mapped to OO methods. The request declaration specifies the input parameter name and type, and the response declaration specifies the type returned by the method.
9. To allow for commands with multiple input parameters, use the reserved keyword InputParams as the value of the Name of a Request. Then:
   Declare the Schema of the Request as type Object.
   Use the fields array of the schema to enter the desired multiple input parameters.
10. Similarly, to allow for commands with multiple outputs, use the reserved keyword Output as the value of the Name of a Response. Then:
   Declare the Schema of the Response as type Object.
   Use the fields array of the schema to enter the desired multiple output values.

Based on the fact that DTDL Relationships may have Properties (and a digital twin may have several relationships), the concept of typed relationships 630 are introduced, where predefined DTDL Relationships names dictate the behavior of source code generation in an arbitrary OO programming language.

This representation consists of a character string separated by the “_” character. The first half is the general descriptor, and the second the specific descriptor:
<general>_<specific>

This representation can be used in several ways, depending on specific code generation software. For example, this representation can be used as follows:
The <general> string part carries the type of the relationship; i.e., how both instances relate to each other, giving therefore hints to the code generator about the behavior of the relationship.
The <specific> string part is not only a disambiguating element, for two DTDL Relationships cannot have the same name, but it can also be used to specialize further the connection between both instances.

A specific instance of a typed relationship 630 is the BindEvent typed relationship. The BindEvent typed relationship is a DTDL relationship with name “BindEvent” for a digital twin, where the target of the relationship will be the ID of the target digital twin.

It is then defined in the relationship a DTDL Property whose schema consists of a DTDL Map. The “Map key” is the Property or telemetry that will be updated as a consequence for the update of the Property or Telemetry described by the “Map Value”. The source code generator 640 will use the DTDL to create three methods based on the following templates:
1. Bind_<mapKey>_<mapValue>(<target> pub)
   This method allows the digital twin instance to refer to a specific <target> instance and to add the generated event handler to that instance.
2. Update_<mapKey>_<mapValue>(object? Sender, EventArgs e)
   This method is an event handler method that will be called when the property <mapValue> of the referred <target> instance changes its value.
3. <target>.<mapValue>.“schema” ResolvePayload_<mapKey>_<mapValue>(object? Sender, EventArgs e)
   This method is optional and is an opportunity to transform the type of the target telemetry <mapValue> into the type of the source telemetry <mapKey>.

Source code generators such as the source code generator 640 can be tailored to behave differently, depending on the amount of source code for a DTDL model that was already generated. For instance, a source code generation application can accept as input parameters the path for a folder containing DTDL models and the path for a folder where the source code will be generated—the output folder. If this output folder already contains files which in turn contain classes or methods that have the same name of classes or its attributes to be generated, the source code generator 640 can take three different actions or a combination of them, depending on specific circumstances:
Warn and Stop: report the name conflicts and interrupts the code generation process, not generating code;
Additive: in case of methods that already exist, add the generated source code to the methods without interfering with the existing code;
Overwrite: overwrite the methods that already exist.

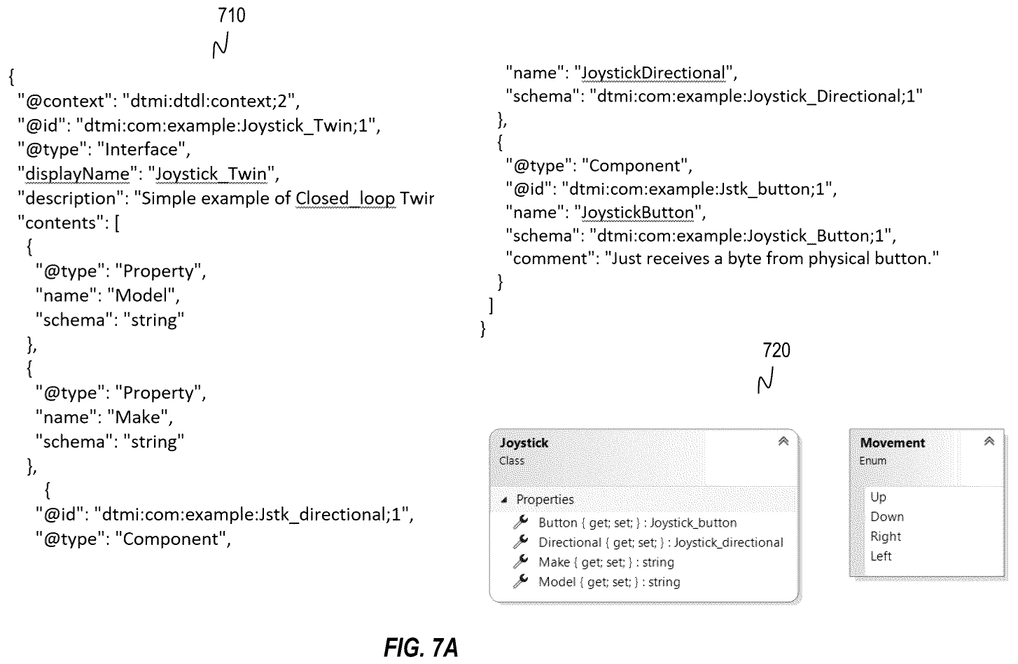

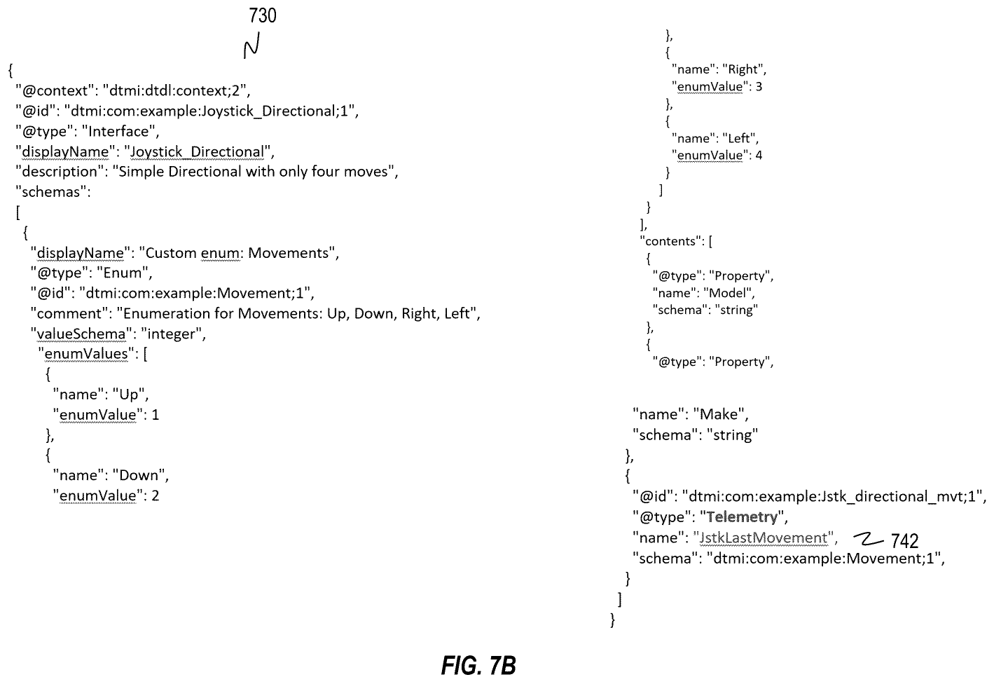

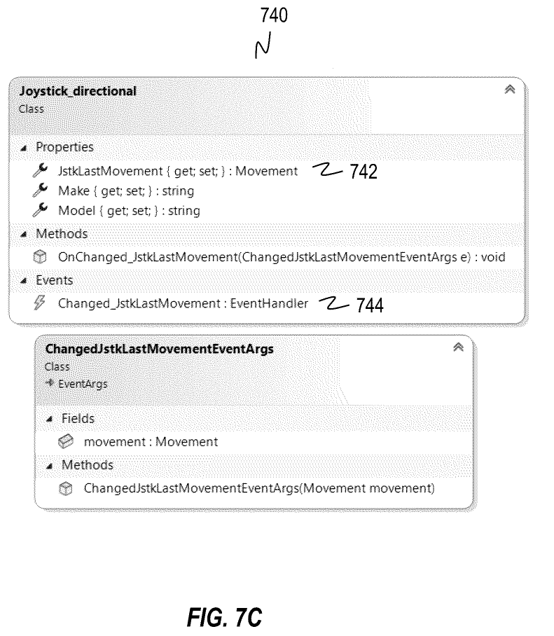

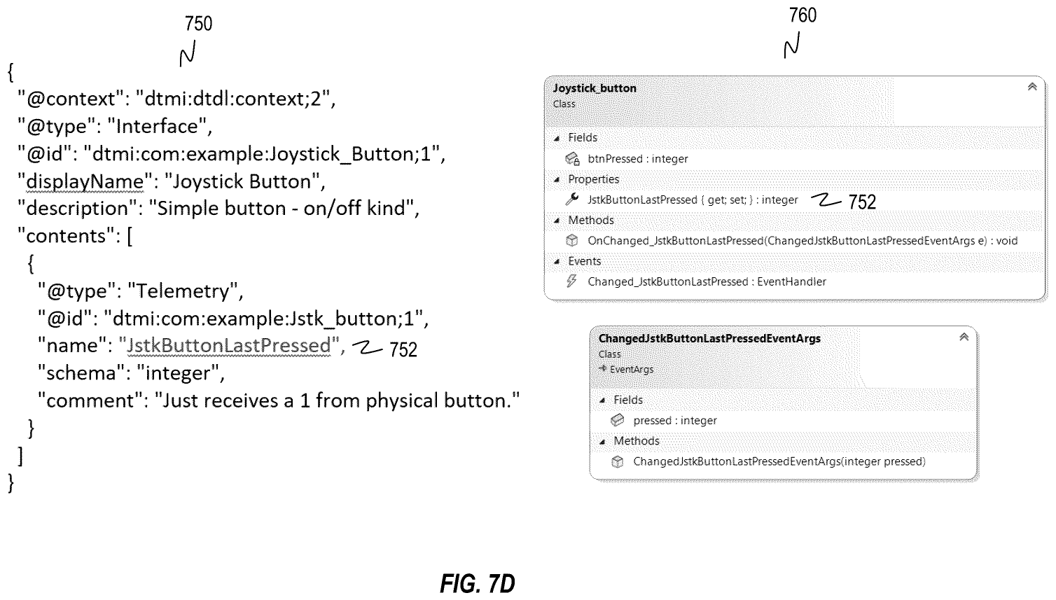

FIGS. 7A-7D illustrate a DTDL model for a joystick having only two components, a directional and a button. FIG. 7A shows a high-level DTDL model 710 of the joystick. FIG. 7A also shows at 720 a simple OO Class Diagram, where the directional and the button are properties of the joystick, meaning that each instance of a Joystick will contain an instance of a directional and an instance of a button. It will be appreciated that in the embodiment of FIG. 7A, the joystick digital twin will not accept telemetry data itself, rather the directional and button components or properties will receive the telemetry data.

The directional component accepts as telemetry payload an enumeration: {Up, Down, Right, Left}, which could be transmitted as a string or a number. FIG. 7B illustrates the DTDL model 730 for the directional component.

FIG. 7C illustrates the OO representation of the source code 650 generated by the code generator 640 from the DTDL model 730 for the joystick directional class 740. It will be appreciated that the generated code of the OO representation follows the general rules for code generation discussed previously. It allows methods of any other classes to run as soon as the property JstkLastMovement 742 changes, by exposing the Changed_JstkLastMovement event 744.

The button component accepts as telemetry payload simply any value representing that the button was pressed. FIG. 7D illustrates the DTDL model 750 for the button component. Analogous to the directional component, the button component has only one Telemetry DTDL element, named “JstkButton|LastPressed” 752. FIG. 7D illustrates the OO representation 760 of the source code 650 generated by the code generator 640 from the DTDL model 750 for the button component.

As mentioned previously, typed relationships 630 are predefined DTDL Relationships names that dictate the behavior of source code generation in an arbitrary OO programming language. In particular, the BindEvent typed relationship is a DTDL relationship with name “BindEvent” for a digital twin, where the target of the relationship will be the ID of the target digital twin. Examples of the BindEvent typed relationship will now be explained.

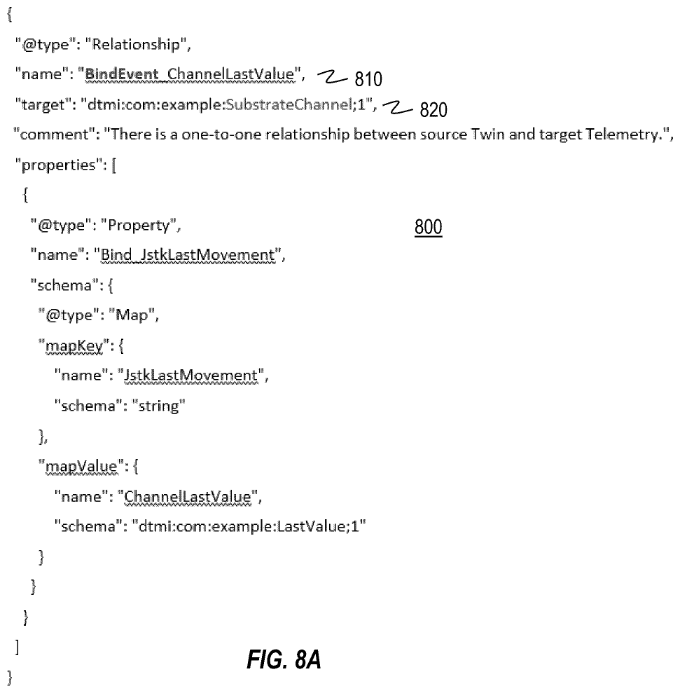

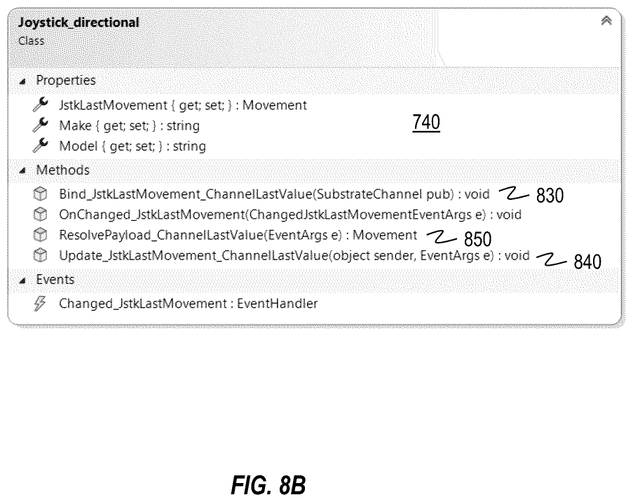

FIG. 8A shows how the BindEvent typed relationship between the DTDL joystick directional model 730, and the DTDL substrate channel model (see Appendix) will generate the source code that links the generated OO classes in an event publisher-subscriber fashion. Specifically, FIG. 8A shows the DTDL relationship description 800 that needs to be added to the DTDL joystick directional model 730. The DTDL relationship description 800 includes the BindEvent typed relationship as shown at 810 that specifies the target as being the substrate channel as shown at 820.

FIG. 8B illustrates the OO generated source code 650 for the DTDL joystick directional model that includes the DTDL relationship description 800. Based on the DTDL relationship description 800, three methods are added to the joystick directional class 740 by the code generator 640. That is, the joystick directional class 740 shown in FIG. 8B includes three methods that are not seen in the joystick directional class 740 shown in FIG. 7C. The three methods are:

| | |
|---|---|
| 1. | Bind_JstkLastMovement_ChannelLastValue(SubstrateChannel pub) 830, which |

allows a joystick_directional instance to refer to a specific SubstrateChannel instance and
to add the generated event handler to that instance. An example of OO code for this
method is as follows:

| | |
|---|---|
| | public void Bind_JstkLastMovement_ChannelLastValue(SubstrateChannel pub) |
| | { |
| | // Adds the generated Event handler to an instance |
| | // of the SubstrateChannel.ChanneLastValue |
| | // |
| | pub.Changed_ChannelLastValue += |
| | Update_JstkLastMovement_ChannelLastValue; |
| | } |
| 2. | Update_JstkLastMovement_ChannelLastValue(object? sender, EventArgs e) 840, |

which is an event handler method that will be called when the property ChannelLastValue
of the referred SubstrateChannel instance changes its value. An example of OO code for
this method is as follows:

| | |
|---|---|
| | public void Update_JstkLastMovement_ChannelLastValue(object? sender, |
| | EventArgs e) |
| | { |
| | this.JstkLastMovement = this.ResolvePayload_ChannelLastValue(e); |
| | } |
| 3. | ResolvePayload_ChannelLastValue(EventArgs e) 850, which is optional and is an |

opportunity to transform the type of the target telemetry into the type of the source
telemetry. An example of OO code for this method is as follows:

```
  public Movement ResolvePayload_ChannelLastValue(EventArgs e)
  {
  var e_ChannelLastValueEventArgs = e as ChangedChannelLastValueEventArgs;
  // Specific code to change payload, if needed
  //
  // var newMovement = /* create new Movement from specialized EventArgs */
  }
```

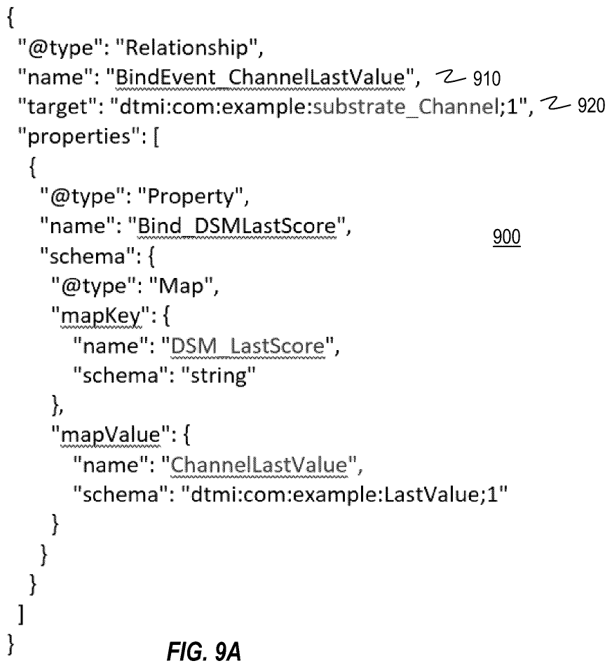

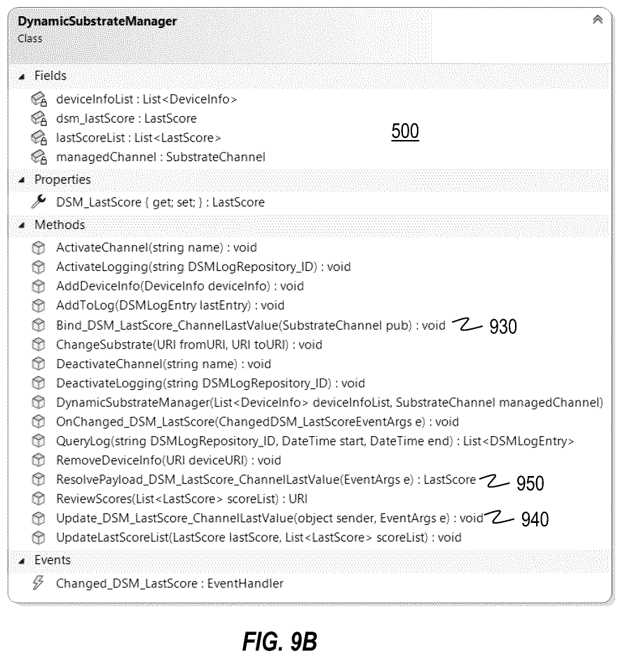

FIG. 9A shows how the BindEvent typed relationship between the DTDL dynamic substrate manager model (see Appendix) and the DTDL substrate channel model (see Appendix) will generate the source code that links the generated OO classes in an event publisher-subscriber fashion. Specifically, FIG. 9A shows the DTDL dynamic substrate manager model. The DTDL relationship description 900 includes the BindEvent typed relationship as shown at 910 that specifies the target as being the substrate channel as shown at 920.

FIG. 9B illustrates the OO generated source code 650 for the DTDL dynamic substrate manager model that includes the DTDL relationship description 900. Based on the DTDL relationship description 900, three methods are added to the dynamic substrate manager class 500 by the code generator 640. That is, the dynamic substrate manager class 500 shown in FIG. 9B includes three methods that are not seen in the dynamic substrate manager class 500 shown in FIG. 5A. The three methods are:

| | |
|---|---|
| 1. | Bind_DSM_LastScore_ChannelLastValue(SubstrateChannel pub) 930, which |

```
  allows a Dynamic Substrate Manager instance to refer to a specific SubstrateChannel
  instance and to add the generated event handler to that instance. An example of OO
  code for this method is as follows:
  public void Bind_DSM_LastScore_ChannelLastValue(SubstrateChannel pub)
  {
    // Adds the generated Event handler to an instance
    // of the SubstrateChannel.ChanneLastValue
    //
    pub.Changed_ChannelLastValue += Update_DSM_LastScore_ChannelLastValue;
  }
```

| | |
|---|---|
| 2. | Update_DSM_LastScore_ChannelLastValue(object? sender, EventArgs e) 940, |

```
  which is an event handler method that will be called when the property ChannelLastValue
  of the referred SubstrateChannel instance changes its value. An example of OO code for
  this method is as follows:
  public void Update_DSM_LastScore_ChannelLastValue (object? sender, EventArgs e)
  {
  this.DSM_LastScore = this. DSM_LastScore _ChannelLastValue(e);
  }
```

| | |
|---|---|
| 3. | ResolvePayload_DSM_LastScore_ChannelLastValue(EventArgs e) 950, which is |

```
optional and is an opportunity to transform the type of the target telemetry into the type of the
source telemetry. An example of OO code for this method is as follows:
  public LastScore ResolvePayload_DSM_LastScore_ChannelLastValue (EventArgs e)
  {
  // Specific code to change payload, if needed
  var e_ChannelLastValueEventArgs = e as ChangedChannelLastValueEventArgs
  }
```

The following is a discussion of aspects of example operating environments for various embodiments of the invention. This discussion is not intended to limit the scope of the invention, or the applicability of the embodiments, in any way.

In general, embodiments of the invention may be implemented in connection with systems, software, and components, that individually and/or collectively implement, and/or cause the implementation of, digital twin operations, digital twin construction operations, digital twin orchestration operations, code generation operations, command operations, and/or command dependency operations.

In general, the scope of the invention is not limited to any particular data platform or data storage environment.

New and/or modified data collected and/or generated in connection with some embodiments, may be stored in an environment that may take the form of a public or private cloud storage environment, an on-premises storage environment, and hybrid storage environments that include public and private elements. Any of these example storage environments, may be partly, or completely, virtualized.

Example cloud computing environments, which may or may not be public, include storage environments that may provide data protection functionality for one or more clients. Another example of a cloud computing environment is one in which processing, data protection, and other, services may be performed on behalf of one or more clients. Some example cloud computing environments in connection with which embodiments of the invention may be employed include, but are not limited to, Microsoft Azure, Amazon AWS, Dell EMC Cloud Storage Services, and Google Cloud. More generally however, the scope of the invention is not limited to employment of any particular type or implementation of cloud computing environment.

In addition to the cloud environment, the operating environment may also include one or more clients that are capable of collecting, modifying, and creating, data. As such, a particular client may employ, or otherwise be associated with, one or more instances of each of one or more applications that perform such operations with respect to data. Such clients may comprise physical machines, containers, or virtual machines (VMs).

Particularly, devices in the operating environment may take the form of software, physical machines, containers, or VMs, or any combination of these, though no particular device implementation or configuration is required for any embodiment. Similarly, data protection system components such as databases, storage servers, storage volumes (LUNs), storage disks, replication services, backup servers, restore servers, backup clients, and restore clients, for example, may likewise take the form of software, physical machines, or virtual machines (VM), though no particular component implementation is required for any embodiment.

Example embodiments of the invention are applicable to any system capable of storing and handling various types of objects, in analog, digital, or other form. Although terms such as document, file, segment, block, or object may be used by way of example, the principles of the disclosure are not limited to any particular form of representing and storing data or other information. Rather, such principles are equally applicable to any object capable of representing information.

It is noted with respect to the disclosed methods, that any operation(s) of any of these methods, may be performed in response to, as a result of, and/or, based upon, the performance of any preceding operation(s). Correspondingly, performance of one or more operations, for example, may be a predicate or trigger to subsequent performance of one or more additional operations. Thus, for example, the various operations that may make up a method may be linked together or otherwise associated with each other by way of relations such as the examples just noted. Finally, and while it is not required, the individual operations that make up the various example methods disclosed herein are, in some embodiments, performed in the specific sequence recited in those examples. In other embodiments, the individual operations that make up a disclosed method may be performed in a sequence other than the specific sequence recited.

Following are some further example embodiments of the invention. These are presented only by way of example and are not intended to limit the scope of the invention in any way.

Embodiment 1. A method comprising: accessing a definition document that defines a digital twin; generating, based on the definition document, a substrate channel component that is configured to be used by the digital twin to communicate with a plurality of physical entities that provide data to the digital twin; and generating, based on the definition document, a dynamic substrate manager component that is configured to dynamically select which of the plurality of physical entities that the digital twin is to be in active communication with so that the selected physical entity can provide data to the digital twin.

Embodiment 2. The method of embodiment 1, further comprising logging, by the substrate channel component, a last data value for each of the plurality of physical devices, the last data value representing the most recent data received by the substrate channel component from each of the plurality of physical devices.

Embodiment 3. The method of embodiment 1 and/or 2, further comprising generating, by the substrate channel component, a confidence score for each of the last data values received from each of the plurality of physical entities.

Embodiment 4. The method of embodiment 1, 2, and/or 3, further comprising logging, by the substrate channel component, historical last data values in a persistent data repository.

Embodiment 5. The method of embodiment 1, 2, 3, and/or 4, wherein dynamically selecting, by the dynamic substrate manager component, which of the plurality of physical entities that the digital twin is to be in active communication with the digital twin comprises receiving a confidence score for each of the plurality of physical devices from the substrate channel component, the confidence scores being a measure of the reliability of data received from the plurality of physical entities; and using the confidence scores to select which physical entity is to be in active communication with the digital twin.

Embodiment 6. The method of embodiment 1, 2, 3, 4, and/or 5, wherein the dynamic substrate manager component selects the physical entity having the highest confidence score.

Embodiment 7. The method of embodiment 1, 2, 3, 4, 5, and/or 6, further comprising selecting by dynamic substrate channel component a first one of the plurality of physical entities based on the confidence scores to be in active communication with the digital twin during a first time period; determining, based on the confidence scores, during a second time period that a second one of the plurality of physical entities should be in active communication with the digital twin; and causing the substrate channel component to change the active communication with the digital twin from the first one of the plurality of physical entities to the second one of the plurality of second entities.

Embodiment 8. The method of embodiment 1, 2, 3, 4, 5, 6, and/or 7, further comprising generating code in a programming language from the definition document by a code generator.

Embodiment 9. The method of embodiment 1, 2, 3, 4, 5, 6, 7, and/or 8, wherein the programming language is an object oriented programming language.

Embodiment 10. The method of embodiment 1, 2, 3, 4, 5, 6, 7, 8, and/or 9, wherein the generated code is based in part on a binding relationship that binds one object to another object, wherein code for the binding relationship is generated using rules that are different from rules used to generate code from other types of relationships and properties in the definition document.

Embodiment 11. The method as recited in any of embodiments 1-10 or in any combination therein or in any combination of any portion therein.

Embodiment 12. A system, comprising hardware and/or software, operable to perform any of the operations, methods, or processes, or any portion of any of these, or any combination thereof, disclosed herein.

Embodiment 13. A non-transitory storage medium having stored therein instructions that are executable by one or more hardware processors to perform operations comprising the operations of any one or more of embodiments 1-12.

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

As indicated above, embodiments within the scope of the present invention also include computer storage media, which are physical media for carrying or having computer-executable instructions or data structures stored thereon. Such computer storage media may be any available physical media that may be accessed by a general purpose or special purpose computer.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality of the invention. Combinations of the above should also be included within the scope of computer storage media. Such media are also examples of non-transitory storage media, and non-transitory storage media also embraces cloud-based storage systems and structures, although the scope of the invention is not limited to these examples of non-transitory storage media.

Computer-executable instructions comprise, for example, instructions and data which, when executed, cause a general-purpose computer, special purpose computer, or special purpose processing device to perform a certain function or group of functions. As such, some embodiments of the invention may be downloadable to one or more systems or devices, for example, from a website, mesh topology, or other source. Also, the scope of the invention embraces any hardware system or device that comprises an instance of an application that comprises the disclosed executable instructions.

Although the subject matter has been described in language specific to structural features and/or methodological acts, it is to be understood that the subject matter defined in the appended claims is not necessarily limited to the specific features or acts described above. Rather, the specific features and acts disclosed herein are disclosed as example forms of implementing the claims.

As used herein, the term ‘module’ or ‘component’ may refer to software objects or routines that are executed on the computing system. The different components, modules, engines, and services described herein may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments of the invention may be performed in client-server environments, whether network or local environments, or in any other suitable environment. Suitable operating environments for at least some embodiments of the invention include cloud computing environments where one or more of a client, server, or other machine may reside and operate in a cloud environment.

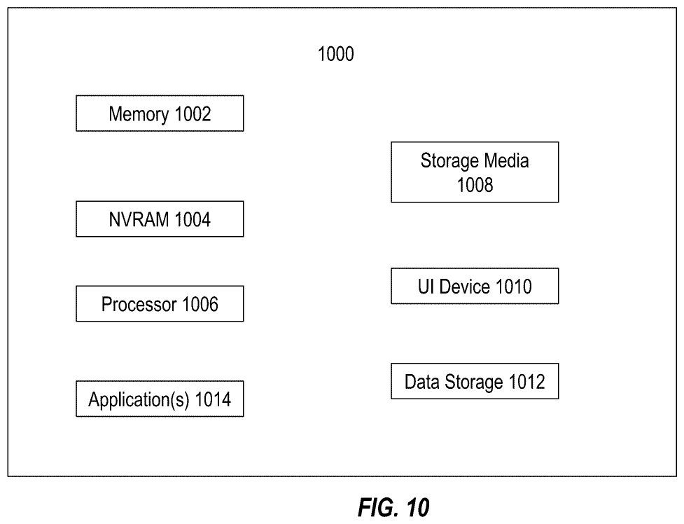

With reference briefly now to FIG. 10, any one or more of the entities disclosed, or implied, by the Figures and/or elsewhere herein, may take the form of, or include, or be implemented on, or hosted by, a physical computing device, one example of which is denoted at 1000. Also, where any of the aforementioned elements comprise or consist of a virtual machine (VM), that VM may constitute a virtualization of any combination of the physical components disclosed in FIG. 10.

In the example of FIG. 10, the physical computing device 1000 includes a memory 1002 which may include one, some, or all, of random-access memory (RAM), non-volatile memory (NVM) 1004 such as NVRAM for example, read-only memory (ROM), and persistent memory, one or more hardware processors 1006, non-transitory storage media 1008, UI device 1010, and data storage 1012. One or more of the memory components 1002 of the physical computing device 1000 may take the form of solid-state device (SSD) storage. Also, one or more applications 1014 may be provided that comprise instructions executable by one or more hardware processors 1006 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method, comprising:
accessing a definition document that defines a digital twin;
generating, based on the definition document, a substrate channel component that is configured to be used by the digital twin to communicate with a plurality of physical entities that provide data to the digital twin; and
generating, based on the definition document, a dynamic substrate manager component that is configured to dynamically select which of the plurality of physical entities that the digital twin is to be in active communication with so that the selected physical entity can provide data to the digital twin.

2. The method of claim 1, further comprising:
logging, by the substrate channel component, a last data value for each of the plurality of physical entities, the last data value representing a most recent data received by the substrate channel component from each of the plurality of physical entities.

3. The method of claim 2, further comprising:
generating, by the substrate channel component, a confidence score for each of the last data values received from each of the plurality of physical entities.

4. The method of claim 3, further comprising:
logging, by the substrate channel component, historical last data values in a persistent data repository.

5. The method of claim 1, wherein dynamically selecting, by the dynamic substrate manager component, which of the plurality of physical entities that the digital twin is to be in active communication with the digital twin comprises:
receiving a confidence score for each of the plurality of physical entities from the substrate channel component, the confidence scores being a measure of a reliability of data received from the plurality of physical entities; and
using the confidence scores to select which physical entity is to be in active communication with the digital twin.

6. The method of claim 5, wherein the dynamic substrate manager component selects the physical entity having a highest confidence score.

7. The method of claim 5, further comprising:
selecting by dynamic substrate channel component a first one of the plurality of physical entities based on the confidence scores to be in active communication with the digital twin during a first time period;
determining, based on the confidence scores, during a second time period that a second one of the plurality of physical entities should be in active communication with the digital twin; and
causing the substrate channel component to change the active communication with the digital twin from the first one of the plurality of physical entities to the second one of the plurality of second entities.

8. The method of claim 1, further comprising generating code in a programming language from the definition document by a code generator.

9. The method of claim 8, wherein the programming language is an object oriented programming language.

10. The method of claim 8, wherein the generated code is based in part on a binding relationship that binds one object to another object, wherein code for the binding relationship is generated using rules that are different from rules used to generate code from other types of relationships and properties in the definition document.

11. A non-transitory storage medium having stored therein instructions that are executable by one or more hardware processors to perform operations comprising:
accessing a definition document that defines a digital twin;
generating, based on the definition document, a substrate channel component that is configured to be used by the digital twin to communicate with a plurality of physical entities that provide data to the digital twin; and
generating, based on the definition document, a dynamic substrate manager component that is configured to dynamically select which of the plurality of physical entities that the digital twin is to be in active communication with so that the selected physical entity can provide data to the digital twin.

12. The non-transitory storage medium of claim 11, further comprising:
logging, by the substrate channel component, a last data value for each of the plurality of physical entities, the last data value representing a most recent data received by the substrate channel component from each of the plurality of physical entities.

13. The non-transitory storage medium of claim 12, further comprising:
generating, by the substrate channel component, a confidence score for each of the last data values received from each of the plurality of physical entities.

14. The non-transitory storage medium of claim 13, further comprising:
logging, by the substrate channel component, historical last data values in a persistent data repository.

15. The non-transitory storage medium of claim 11, wherein the operation of dynamically selecting, by the dynamic substrate manager component, which of the plurality of physical entities that the digital twin is to be in active communication with the digital twin further comprises:
receiving a confidence score for each of the plurality of physical entities from the substrate channel component, the confidence scores being a measure of a reliability of data received from the plurality of physical entities; and
using the confidence scores to select which physical entity is to be in active communication with the digital twin.

16. The non-transitory storage medium of claim 15, wherein the dynamic substrate manager component selects the physical entity having a highest confidence score.

17. The non-transitory storage medium of claim 15, further comprising:
selecting by dynamic substrate channel component a first one of the plurality of physical entities based on the confidence scores to be in active communication with the digital twin during a first time period;
determining, based on the confidence scores, during a second time period that a second one of the plurality of physical entities should be in active communication with the digital twin; and
causing the substrate channel component to change the active communication with the digital twin from the first one of the plurality of physical entities to the second one of the plurality of second entities.

18. The non-transitory storage medium of claim 11, further comprising an operation of generating code in a programming language from the definition document by a code generator.

19. The non-transitory storage medium of claim 18, wherein the programming language is an object oriented programming language.

20. The non-transitory storage medium of claim 18, wherein the generated code is based in part on a binding relationship that binds one object to another object, wherein code for the binding relationship is generated using rules that are different from rules used to generate code from other types of relationships and properties in the definition document.
